(19) United States
(12) Patent Application Publication
(10) Pub. No.: US 2021/0397762 A1
(43) Pub. Date: Dec. 23, 2021

(54) DISTRIBUTION GRID ADMITTANCE ESTIMATION WITH LIMITED NONSYNCHRONIZED MEASUREMENTS

(71) Applicant: Siemens Aktiengesellschaft, Munich (DE)

(72) Inventors: Xia Miao, Cambridge, MA (US); Xiaofan Wu, North Brunswick, NJ (US); Ulrich Muenz, Princeton, NJ (US)

(21) Appl. No.: 17/289,268

(22) PCT Filed: Aug. 23, 2019
(86) PCT No.: PCT/US2019/047801

§ 371 Date: Apr. 28, 2021

Related U.S. Application Data
(60) Provisional application No. 62/756,311, filed on Nov. 6, 2018.

(51) Int. Cl. G06F 30/18; H02J 13/00

(52) U.S. Cl. CPC G06F 30/18; H02J 13/00006; H02J 2203/20; H02J 2203/10; H02J 13/00034

(57) ABSTRACT

A method of estimating grid admittance is provided and includes receiving an input of a network topology of a distribution grid, categorizing nodes of the network topology of the distribution grid into node-cases, for each node-case, executing a network admittance estimation algorithm from available measurement information and determining a network admittance estimate for the distribution grid with the network topology from results of the network admittance estimation algorithm executed for each node-case.

### BACKGROUND

The present invention relates generally to distribution grid admittance with limited non-synchronized measurements, and more particularly, to methods of applying distribution grid admittance estimations with limited non-synchronized measurements.

Grid admittance matrix information is often of great importance for power systems analysis and operation in distribution systems. This is especially true in view of increasing integration of distributed energy resources like photovoltaic sources, battery storage and requirements for electric vehicle charging.

Conventionally, the admittance matrix of a distribution system is not needed for managing and controlling operations of a distribution system. However, because of the increasing use of distributed energy resources (DERs) and the corresponding required use of new distributed energy resource management system (DERMS), accurate information about grid admittance matrix is becoming more and more important to obtain. Relevant applications include algorithms for power flow and optimal power flow analysis, stability analysis, monitoring, fault detection and control of the grid.

### SUMMARY

According to an aspect of the disclosure, a method of estimating grid admittance is provided and includes receiving an input of a network topology of a distribution grid, categorizing nodes of the network topology of the distribution grid into node-cases, for each node-case, executing a network admittance estimation algorithm from available measurement information and determining a network admittance estimate for the distribution grid with the network topology from results of the network admittance estimation algorithm executed for each node-case.

In accordance with additional or alternative embodiments, the distribution grid includes a relatively low voltage tree structure and is electrically coupled to a transmission network including a relatively high voltage mesh network.

In accordance with additional or alternative embodiments, the categorizing is executed in a bottom-up direction.

In accordance with additional or alternative embodiments, the available measurement information is derived from devices distributed throughout the distribution grid.

In accordance with additional or alternative embodiments, the node-cases include a case in which devices are present at parent and child nodes of a line of the distribution grid, a case in which a device is only present at a parent node of a line of the distribution grid, a case in which a device is only present at a child node of a line of the distribution grid and a case in which no device is present at parent or child nodes of a line of the distribution grid.

In accordance with additional or alternative embodiments, the network admittance estimation algorithm includes one of a hybridized data-physics approach and an optimization-based approach.

According to another aspect of the disclosure, a computer-implemented method of estimating grid admittance is provided and includes receiving an input of a network topology of a distribution grid, categorizing nodes of the network topology of the distribution grid into node-cases, for each node-case, executing a network admittance estimation algorithm from available measurement information and determining a network admittance estimate for the distribution grid with the network topology from results of the network admittance estimation algorithm executed for each node-case.

In accordance with additional or alternative embodiments, the distribution grid includes a relatively low voltage tree structure and is electrically coupled to a transmission network including a relatively high voltage mesh network.

In accordance with additional or alternative embodiments, the categorizing is executed in a bottom-up direction.

In accordance with additional or alternative embodiments, the available measurement information is derived from devices distributed throughout the distribution grid.

In accordance with additional or alternative embodiments, the node-cases include a case in which devices are present at parent and child nodes of a line of the distribution grid, a case in which a device is only present at a parent node of a line of the distribution grid, a case in which a device is only present at a child node of a line of the distribution grid and a case in which no device is present at parent or child nodes of a line of the distribution grid.

In accordance with additional or alternative embodiments, the network admittance estimation algorithm includes one of a hybridized data-physics approach and an optimization-based approach.

According to another aspect of the disclosure, a non-iterative method of designing a controller of an inverter for installation in a distribution grid is provided. The method includes estimating a grid admittance of the distribution grid by receiving an input of a network topology of a distribution grid, categorizing nodes of the network topology of the distribution grid into node-cases, executing a network admittance estimation algorithm from available measurement information for each node-case and determining a network admittance estimate for the distribution grid with the network topology from results of the network admittance estimation algorithm executed for each node-case and designing the controller of the inverter with a characteristic inverter control signal based on the network admittance estimate in accordance with a design model.

In accordance with additional or alternative embodiments, the method further includes installing the inverter with the controller in the distribution grid.

In accordance with additional or alternative embodiments, the distribution grid includes a relatively low voltage tree structure and is electrically coupled to a transmission network including a relatively high voltage mesh network.

In accordance with additional or alternative embodiments, the categorizing is executed in a bottom-up direction.

In accordance with additional or alternative embodiments, the available measurement information is derived from devices distributed throughout the distribution grid.

In accordance with additional or alternative embodiments, the node-cases include a case in which devices are present at parent and child nodes of a line of the distribution grid, a case in which a device is only present at a parent node of a line of the distribution grid, a case in which a device is only present at a child node of a line of the distribution grid and a case in which no device is present at parent or child nodes of a line of the distribution grid.

In accordance with additional or alternative embodiments, the network admittance estimation algorithm includes one of a hybridized data-physics approach and an optimization-based approach.

In accordance with additional or alternative embodiments, the method further comprises testing an operation of the inverter following the installing of the inverter in the distribution grid and updating the design model based on results of the testing.

### BRIEF DESCRIPTION OF THE DRAWINGS

The detailed description is set forth with reference to the accompanying drawings. The drawings are provided for purposes of illustration only and merely depict example embodiments of the invention. The drawings are provided to facilitate understanding of the invention and shall not be deemed to limit the breadth, scope, or applicability of the invention. In the drawings, the left-most digit(s) of a reference numeral identifies the drawing in which the reference numeral first appears. The use of the same reference numerals indicates similar, but not necessarily the same or identical components. However, different reference numerals may be used to identify similar components as well. Various embodiments may utilize elements or components other than those illustrated in the drawings, and some elements and/or components may not be present in various embodiments. The use of singular terminology to describe a component or element may, depending on the context, encompass a plural number of such components or elements and vice versa.

FIG. 1 is a schematic diagram of a distribution grid in accordance with embodiments;

FIG. 2 is a table illustrating four cases of nodes into which a distribution grid can be categorized in accordance with embodiments;

FIG. 3 is a flow diagram illustrating a method of network topology categorization in accordance with embodiments;

FIG. 4 is a diagram illustrating line impedance and current in accordance with embodiments; and

FIG. 5 is a flow diagram illustrating a non-iterative method of designing an inverter for installation in a distribution grid in accordance with embodiments.

### DETAILED DESCRIPTION

As will be described below, a method is provided for estimating a radial distribution grid admittance matrix using a limited number of measurement devices. Once the distribution grid admittance matrix is estimated, additional actions can be taken to improve grid performance. These include effecting inverter control design improvements, state estimation efforts and sensor choice and placement refinements.

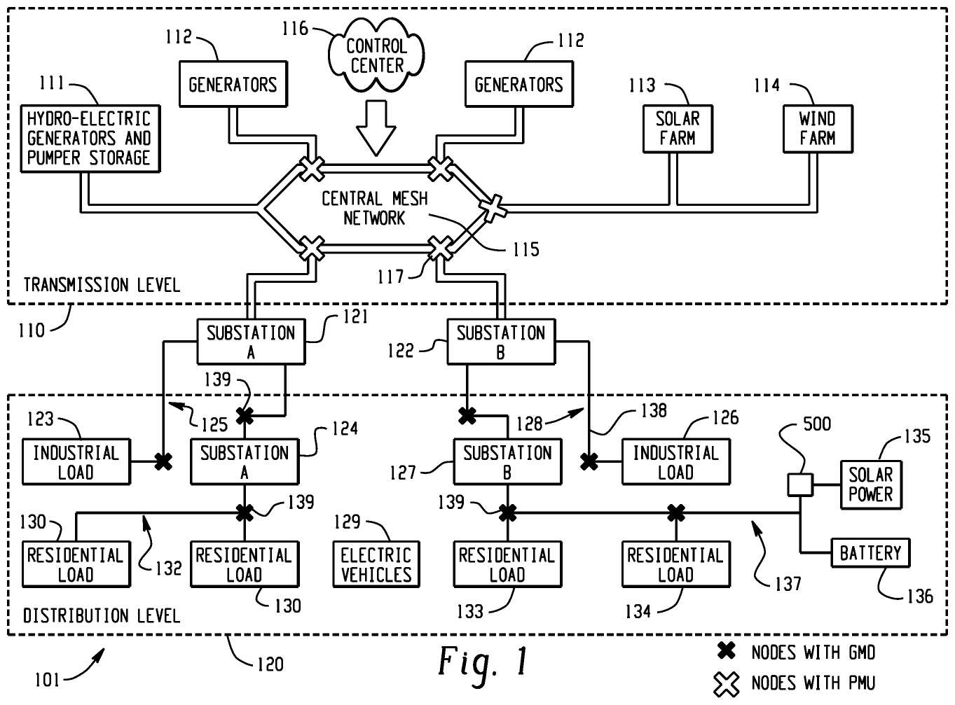

With reference to FIG. 1, a typical power system architecture 101 is provided. The power system architecture 101 includes a transmission level 110 and a distribution grid 120. The transmission level 110 can be provided as a mesh network and can be characterized as a relatively high voltage system. The distribution grid 120, on the other hand, includes a mix of overhead and underground cables, can be arranged in one or more tree structures and can be characterized as a relatively low voltage system. In the exemplary case of FIG. 1, the transmission level 110 includes hydro-electric generators and pumped storage systems 111, generators 112, solar farms 113 and wind farms 114 that are coupled to a central mesh network 115 under the control of a control center 116. The transmission level 110 can also include one or more phasor measurement units (PMUs) 117 at connections of the central mesh network 115. In addition, in the exemplary case of FIG. 1, the distribution grid 120 includes substation A 121 and substation B 122, which are both coupled to the central mesh network 115. As shown, the distribution grid 120 further includes first industrial load 123 and first sub-substation A 124, which are coupled to substation A 121 in a first tree structure 125, and second industrial load 126 and second sub-substation B 127, which are coupled to substation B 122 in a second tree structure 128. Still further, in the exemplary case of FIG. 1, the distribution grid 120 includes electric vehicles 129 and first residential loads 130 and 131, which are coupled to first sub-substation A 124 in a third tree structure 132, and second residential loads 133 and 134 as well as solar paneling 135 and batteries 136, where the second residential loads 133 and 134 are coupled to the second sub-substation B 127 in a fourth tree structure 137 and the solar paneling 135 and batteries 136 are coupled to the second residential load 134. The distribution grid 120 can also include conductive lines 138 by which electricity is transmitted along the various tree structures and one or more grid measurement devices (GMDs) 139 respectively disposed along corresponding ones of the conductive lines 138.

The GMDs 139 are typically inexpensive and accurate but can only provide non-synchronized three-phase real power, reactive power and voltage magnitude readings on a periodic basis. Voltage phase information is not available.

For a variety of single and multi-core cables in distribution grids, their impedances are normally approximated as follows:

L=(K+0:2 ln 2S/d)10⁻⁶

where L is cable inductance (H=m), K is a conductor formation constant, S is axial spacing between conductors within a cable/in trefoil/flat formulation conductors (mm), d is a conductor diameter (mm). Here, L includes both self and mutual inductance. Consequently, phases of cables can be regarded as decoupled from each other, with L of each phase.

In recent decades, while some network admittance estimation methods have been proposed, these methods are primarily designed for use with transmission level grids in which distribution grids may or may not be aggregated. However, as an increasing number of advanced control and communication technologies and DERs become involved at distribution level grids, distribution grids become more responsive and unneglectable. Thus, the availability of accurate distribution grid admittance becomes more critical and has arisen as one of the bottlenecks to achieving flexible, reliable and resilient operations.

At present, however, there are no efficient or practically implementable network admittance estimation methods proposed for distribution grids. This is partially due to the fact that, in many cases, only very few measurement devices are deployed and the available measurement devices are usually low cost, providing non-time-synchronized data (in contrast to expensive PMUs used in transmission systems) over a relatively long time period, the networks are unbalanced in nature and the lines of distribution grids are short and are usually a mix of overhead lines, underground cables, etc., which introduce numerical difficulties. Indeed, while there are existing solutions for transmission grids, they are not feasible for use with distribution grids. For example, single-line impedance/admittance estimation is not feasible for large topologies because too many measurement devices are required, network impedance/admittance estimation is a recursive least square approach on a Thevenin equivalent system which loses the network topology and parameter error estimation/identification relates to methods based on residual sensitivity analysis, methods based on heuristic algorithms, methods based on augmented state vectors or methods based on normalized Lagrange multipliers none of which are typically known for distribution grids. Meanwhile, recent progress for distribution grids involves single-line parameter estimation which is least square approach requiring line measurements at both ends of an estimated line that might not be available, topology and parameter joint estimation where an reliably balanced network with linearized power flow models is considered assuming high-cost PMU measurements are available even though they likely are not available or inverse power flow problem solutions that are based on a traditional regression model unreasonably assuming no measurement errors.

In sum, the available solutions generally require synchronized measurements which require that expensive PMUs be deployed in the distribution grid when they probably cannot in fact be deployed, many solutions require phasor information of all nodes with PMUs which is economically prohibitive, their robustness against communication delay, measurement errors, etc., is questionable, they do not consider unbalanced networks and they often require huge computational effort for large networks that cannot be implemented in real time.

With this in mind, from an implementation point of view, any potential estimation method should at least have the following two features: it must be robust against non-synchronous and low quality measurement data with measurement error, etc., and it must have a reasonably low computational requirement.

Thus, the methods and systems described herein assume that a given network topology is known and that admittances of its power lines and transformers between the buses of the distribution grid are to be estimated with limited measurements (e.g., limited number of measurement devices). It will then be possible to understand the network better and to achieve better performance and accuracy in control design phases. Therefore, the proposed method for network admittance matrix estimation includes a network topology categorization process and a network admittance estimation.

The network topology categorization process aims to break a complicated network into four basic elements. Therefore, parameter estimation of the entire complicated network could be achieved by the composition of standard procedures of basic element estimation, which simplifies the estimation problem.

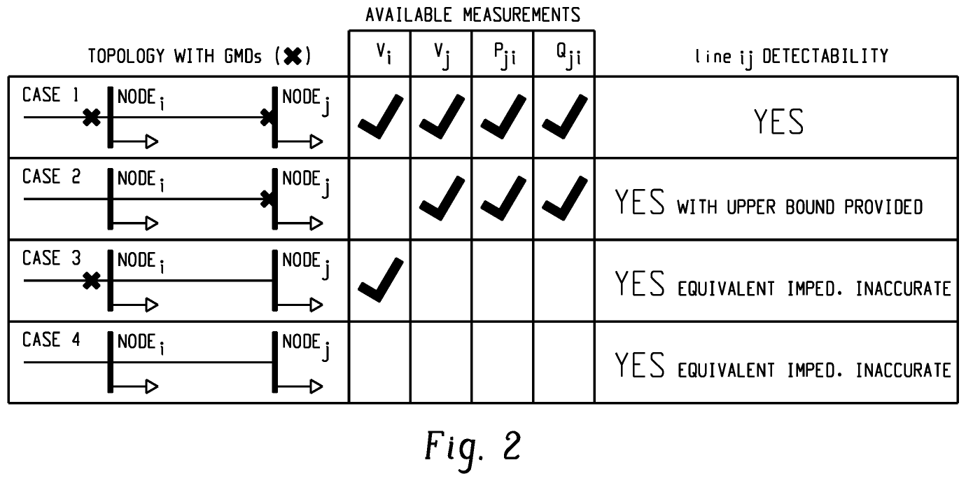

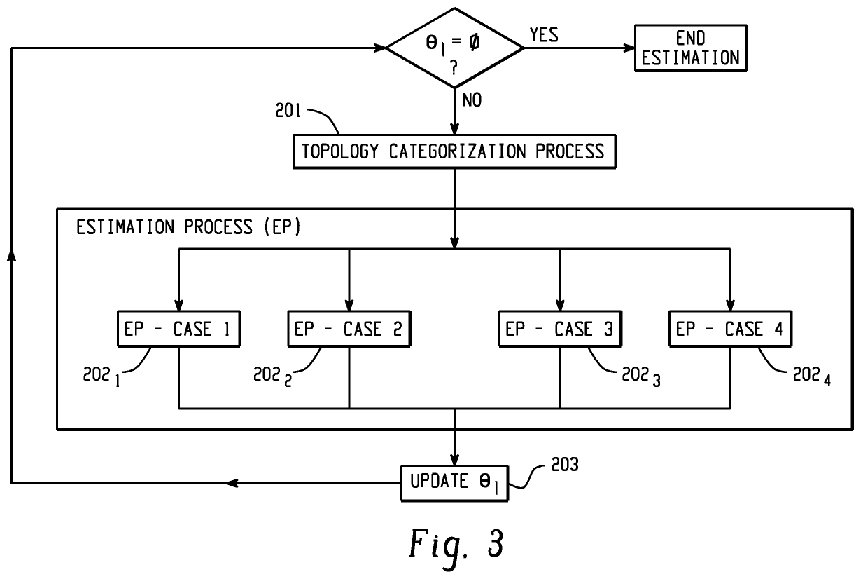

With reference to FIGS. 2 and 3, the network topology categorization aims to break a complicated network down into a few basic elements whereupon admittance estimation can be achieved by the composition of estimation procedures of basic elements.

The network topology categorization is as follows: given a line, let node i represent its parent (sending) node. Thus, the power flows from node i to node j (child node). Based on the location of GMDs, we could have four different line elements. Note that it is impossible to have real and reactive power at both sending (node i) and receiving ends (node j). GMD location and corresponding measurements of each basic element are listed in the table of FIG. 2. According to the available measurements, the detectability of each line element is further concluded and summarized. As shown in FIG. 2, the difference between case 2 and case 3 is: the real and reactive power flow received at node j along line ij is known in case 2 but we only know the total power injection at node i in case 3 because it is possible to have multiple branches connected to node i. Therefore, in case 3 and case 4, it is only possible to provide an equivalent line impedance estimation which includes possible local loads.

The network topology categorization algorithm starts with a measured node. Then, the algorithm explores its connecting lines and compares each line with four basic elements. The following notations are defined: Ωₘ is a set of nodes with GMDs installed, Ω_{N} is a set of nodes without GMDs, Θₗ is the line set, lineᵢⱼ is the line between node i and node j and Ø is the empty set.

As shown in FIG. 3, the network admittance estimation process is iterative and is initiated with a topology categorization process 201 that breaks down a network topology of a distribution grid into four basic types of node relationships: case 1 202₁, case 2 202₂, case 3 202₃ and case 4 202₄. The analysis of each node relationship results in an update value for the line set, Θₗ, in operation 203.

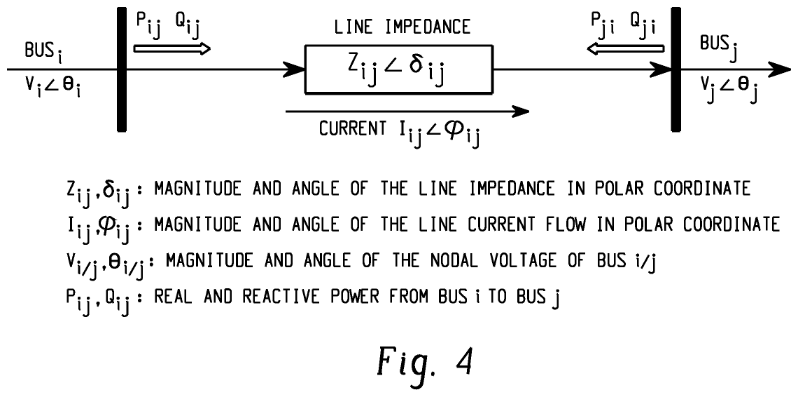

With reference to FIG. 4 and with reference back to FIG. 2, a result of the network admittance estimation process is that certain characteristics of the various nodes and lines of a given distribution grid can be found. In case 1, where a maximum number of GMDs are provided for a line between two nodes, a detectability output for line ij is Zᵢⱼ and δᵢⱼ. In case 2, where a GMD is provided at the parent node for a line between two nodes, a detectability output for line ij is Zᵢⱼ max and δᵢⱼ with an upper bound provided. In case 3, where a GMD is provided at the child node for a line between two nodes, a detectability output for line ij is Z̅ᵢⱼ, δ̅ᵢⱼ equivalent impedance. Lastly, for case 4, where no GMDs are provided at the child or parent nodes for a line between two nodes, a detectability output for line ij is Z̅ᵢⱼ, δ̅ᵢⱼ equivalent impedance.

A detailed explanation of the network admittance estimation process will now be described.

Algorithm 1 Network Topology Decomposition Algorithm

| Input: Ωₘ, Ω_{N}, Θₗ (topology and sensor information) | |
|---|---|
| 1: | Start: Let Ω₁ = Ωₘ, Ω₂ = Ω_{N} |
| 2: | while Θₗ ≠ ∅ do |

| | |
|---|---|
| 3: | if Ω₁ ≠ ∅ then |

| | |
|---|---|
| 4: | Choose a node j ∈ Ω₁ (bottom up direction, i.e. |

child nodes first)

| | |
|---|---|
| 5: | Remove node j from Ω₁ (Ω₁ = Ω₁\node j) |
| 6: | Check if connecting lineᵢⱼ ∈ Θₗ: No→break IF |
| 7: | Check if node i ∈ Ωₘ: Yes→case 1; No→case 2 |

| | |
|---|---|
| 8: | else |

| | |
|---|---|
| 9: | Choose a node j ∈ Ω₂ (bottom up direction) |
| 10: | Remove node j from Ω₂ (Ω₂ = Ω₂\node j) |
| 11: | Check if connecting lineᵢⱼ ∈ Θₗ: No→break IF |
| 12: | Check if node i ∈ Ωₘ: Yes→case 3; No→case 4 |

| | |
|---|---|
| 13: | Remove lineᵢⱼ from Θₗ |

After executing Algorithm 1, the system will be categorized into the basic elements listed in the table of FIG. 3. Different estimation processes for each basic element can therefore be invoked.

With distribution grid cables usually being short and GMD measurements being non-synchronized over certainly periods, it is reasonable to assume that measured data describes a steady-state behavior of a distribution grid and that the following assumption 1 holds: a voltage angle difference between two neighboring nodes is small during normal operation.

Unlike pure data-driven approaches, two important physics and statistics laws form the basis of the disclosed method: Ohm's law and the Law of Large Numbers. Ohm's law provides the relation between physical variables, while the Law of Large Numbers provides an efficient way of interpreting the physical meaning of the data. Thus, one phase of line ij can be used to illustrate the concept. It should be mentioned that, for each case, small modifications might be added. Notations used throughout this section are given (polar coordinate expression) as:

| | | | |
|---|---|---|---|
| Vᵢ | voltage magnitude of node i | Iᵢⱼ | current magnitude |
| θᵢ | voltage angle of node i | φᵢⱼ | current angle |
| Zᵢⱼ | magnitude of line ij impedence | Φᵢ | power factor at node i |
| δᵢⱼ | angle of line ij impedance | | |

Without a loss of generality, it can be assumed that node i is the reference node of line ij and thus has relative 0 voltage angle. Applying Ohm's law we have:

Vᵢ∠Vⱼ∠θⱼ)/Zᵢⱼ∠δᵢⱼ=Iᵢⱼ∠φᵢⱼ (2)

With power factor definition:

Φⱼ=θⱼ−φᵢⱼ cos Φⱼ=Pⱼᵢ/\sqrt{Pⱼᵢ²+Qⱼᵢ²} (3)

whereby:

Vᵢ∠0−Vⱼθⱼ=ZᵢⱼIᵢⱼ∠(θⱼ−Φⱼ+δᵢⱼ) (4)

Thus, two equality constraints can be obtained by matching the magnitude and angle of both sides of equation (4):

(Vᵢ−Vⱼ cos θⱼ)²+(−Vⱼ sin θⱼ)²=Zᵢⱼ²Iᵢⱼ² (5)

−Vⱼ sin θⱼ/(Vᵢ−Vⱼ cos θⱼ)=tan(θⱼ−Φⱼ+δᵢⱼ) (6)

It can be seen that Ohm's law provides relations between measured variables and unknown variables. Next, the Law of Large Number (LLN) and assumption 1 can be used to link the measurement data with the equations (5) and (6).

From a statistics point of view, all the measured data can be regarded as random variables satisfying certain distributions. In particular, as assumption 1 implies that |θⱼ|≈0, it is reasonable to assume that the voltage angle of measured node θⱼ satisfies a distribution with zero mean. To estimate Zᵢⱼ and δᵢⱼ, a method of moments is used. Since Zᵢⱼ and δᵢⱼ do not change much over time, the first order approximation is derived from the measured data. Therefore, the physics and data can be linked through equations (5) (6) as:

Zᵢⱼ²E[Iᵢⱼ²]=[E(Vᵢ−Vⱼ cos θⱼ)²+(−Vⱼ sin θⱼ)²]

E[−Vⱼ sin θⱼ/(Vᵢ−Vⱼ cos θⱼ)]=E[tan(θⱼ−Φⱼ+δᵢⱼ)]

where Iᵢⱼ²=(Pⱼᵢ²+Qⱼᵢ²)/Vⱼ² and E[*] denotes the expectation of variable (*).

Under assumption 1, (E[θⱼ]=0) the equations given above can be further simplified as:

Zᵢⱼ²E[Iᵢⱼ²]=E[(Vᵢ−Vⱼ cos θⱼ)²] (7)

E[tan(−Φⱼ+δᵢⱼ)]=0 (8)

According to the LLN, the expectation in equations (7) and (8) can be approximated by the mean of measured data. Before introducing specific algorithms for each case, feasible regions of voltage magnitudes Vₘᵢₙ and Vₘₐₓ are defined such that Vₘᵢₙ=0.95Vₙₒₘᵢₙₐₗ and Vₘₐₓ=1.05Vₙₒₘᵢₙₐₗ, where Vₙₒₘᵢₙₐₗ is the rated nominal voltage magnitude.

In case 1, the available measurements are three-phase real/reactive power received at node j:

P=(P_{ji,a}[1], . . . ,P_{ji,c}[T]) Q=(Q_{ji,a}[1], . . . ,Q_{ji,c}[T])

and the three-phase voltage magnitude of node i and node j:

Vᵢ=(V_{i,a}[1], . . . ,V_{i,c}[T]) Vⱼ=(V_{j,a}[1], . . . ,V_{j,c}[T])

| Algorithm 2 Estimation algorithm for case 1 | |
|---|---|
| Input: Three-phase measurements: P, Q, Vᵢ, Vⱼ | |
| 1: | Calculate: the exprectation of Vᵢ, Vⱼ, Iᵢⱼ and Φⱼ |
| 2: | ${Φ}_{j} = acos \frac{\vert P \vert}{\sqrt{{P}^{2} + {Q}^{2}}} \to E [ {Φ}_{j} ] = mean ( {Φ}_{j} )$ |
| 3: | ${I}_{ij} = sign ( - P ) \frac{\sqrt{{P}^{2} + {Q}^{2}}}{{V}_{j}} \to E [ {I}_{ij} ] = mean ( {I}_{ij} )$ |
| 4: | E[Vᵢ] = mean(Vᵢ) E[Vⱼ] = mean(Vⱼ) |
| 5: | Estimate impedance magnetude using Eqn.(7): |
| 6: | ${Z}_{ij} = \frac{E [ {V}_{i} ] - E [ {V}_{j} ]}{E [ {I}_{ij} ]}$ |
| 7: | Estimate impedance angle using Eqn.(8): |
| 8: | δᵢⱼ = E[Φⱼ] |

Output: Zᵢⱼ, δᵢⱼ

For case 2, a GMD is only installed at node j. Thus, the available measurements are three-phase real/reactive power received at node j (P/Q) and three-phase voltage magnitude of node j (Vⱼ). In normal operations, voltage should satisfy the feasibility requirement. This indicates that the voltage magnitude of node i (Vᵢ) can vary between Vₘᵢₙ and Vₘₐₓ. An estimation method is shown below in Algorithm 3.

For case 3, a GMD is installed at node i. Besides voltage magnitude at node i (Vᵢ), only three-phase total real/reactive power injection are available: Pᵢ=(P_{i,a}[1], . . . , P_{i,c}[T]) and Qᵢ=(Q_{i,a}[1], . . . , Q_{i,c}[T]). Note that power flow along line ij is unknown and therefore it is assumed that real and reactive power are equally shared by all case 3 type lines connected to node i. The proposed estimation method is shown below in Algorithm 4.

For case 4, no GMDs are present and thus no measurements are available related to the line. However, it is still possible to approximate the impedance by making the following assumption 2: given a node i, it is assumed that all case 4 type lines connected to node i have a same impedance Z and δ. The proposed method for case 4 is shown in Algorithm 5.

| Algorithm 3 Estimation algorithm for case 2 | |
|---|---|
| Input: Three-phase measurements: P, Q, Vᵢ, Vⱼ | |
| | Calculate: E[Vⱼ], E[Iᵢⱼ] and E[Φⱼ] (same as in case 1) |
| 2: | Estimate the upper bound of impedance magnitude: |
| | if E[Iᵢⱼ] > 0 then |
| 4: | $Upper bound \text{:} {\overline{Z}}_{ij} = \frac{{V}_{max} - E [ {V}_{j} ]}{E [ {I}_{ij} ]}$ |
| | else if E[Iᵢⱼ] < 0 then |
| 6: | $Upper bound \text{:} {\overline{Z}}_{ij} = \frac{{V}_{min} - E [ {V}_{j} ]}{E [ {I}_{ij} ]}$ |
| | else |
| 8: | Upper bound: Z̅ᵢⱼ = +∞ |
| | Estimate impedance angle using Eqn.(8): |
| 10: | δᵢⱼ = E[Φⱼ] |

Output: Z̅_{ij,} _{Z}ᵢⱼ = 0 and δᵢⱼ

| Algorithm 4 Estimation algorithm for case 3 | |
|---|---|
| Input: Pᵢ, Qᵢ, Vᵢ and N_{branch} = 1 | |
| 1: | Calculate: (Pⱼ, Qⱼ) ← LowerBound 1( node j): |
| 2: | (Pᵢ, Qᵢ) ← LowerBound 2(node i, node j, N_{branch}); |
| 3: | Calculate: the approximated real/reactive power injection |
| | to the lineᵢⱼ using: |
| 4: | ${P}_{ij} = \frac{E [ {P}_{i} ] - {\underline{P}}_{i} - {\underline{P}}_{j}}{{N}_{branch}} {Q}_{ij} = \frac{E [ {Q}_{i} ] - {\underline{Q}}_{i} - {\underline{Q}}_{j}}{{N}_{branch}}$ |
| 5: | Estimate: Resistance and reactance of equivalent |
| $impedance as \text{:} {R}_{ij} = \frac{{E [ {V}_{i} ]}^{2}}{{P}_{ij}} {X}_{ij} = \frac{{E [ {V}_{i} ]}^{2}}{{Q}_{ij}}$ | |
| $Output \text{:} {Z}_{ij} = \sqrt{{R}_{ij}^{2} + {X}_{ij}^{2}} {δ}_{ij} = atan ( \frac{{X}_{ij}}{{R}_{ij}} )$ | |
| 6: | function LOWERBOUND 1(node j) |
| 7: | for me ∈ child nodes of node i do |
| 8: | if lineⱼₘ has been estimated then |
| 9: | Pⱼₘ = E[Iⱼₘ]²Zⱼₘ cos(δⱼₘ) − E[Pₘⱼ] |
| 10: | Qⱼₘ = E[Iⱼₘ]²Zⱼₘ sin(δⱼₘ) − E[Qₘⱼ] |
| 11: | else |
| 12: | Pⱼₘ = 0 Qⱼₘ = 0 |
| 13: | Return: Pⱼ = Σₘ Pⱼₘ Qⱼ = Σₘ Qⱼₘ |
| 14: | function LOWERBOUND 2(node i, node j, N_{branch}) |
| 15: | for n ∈ child nodes of node i && n ≠ j do |
| 16: | if lineᵢₙ has been estimated then |
| 17: | Pᵢₙ = E[Iᵢₙ]²Zᵢₙ cos(δᵢₙ) − E[Pₙᵢ] |
| 18: | Qᵢₙ = E[Iᵢₙ]²Zᵢₙ sin(δᵢₙ) − E[Qₙᵢ] |
| 19: | else |
| 20: | N_{branch} = N_{branch} + 1 |
| 21: | [Pᵢₙ, Qᵢₙ] ← LowerBound 1 (node n) |
| 22: | Return: Pᵢ = Σₙ Pᵢₙ, Qᵢ = Σₙ Qᵢₙ and N_{branch} |

| Algorithm 5 Estimation algorithm for case 4 | |
|---|---|
| 1: | let N_{branch} = 1 |
| 2: | (Z, δ, N_{branch}) ← Case4(node i, N_{branch}) |
| 3: | Calculate: Zᵢⱼ = Z/N_{branch} δᵢⱼ = δ |
| 4: | Assign Zᵢⱼ, δᵢⱼ to all case 4 type lines in Function Case4 |
| $Output \text{:} {Z}_{ij} = \sqrt{{R}_{ij}^{2} + {X}_{ij}^{2}} {δ}_{ij} = atan ( \frac{{X}_{ij}}{{R}_{ij}} )$ | |
| 5: | function CASE4(node i, N_{branch}) |
| 6: | Find: parent node of node i → node k |
| 7: | if node k has GMD then |
| 8: | (Zₖᵢ, δₖᵢ) ← call: Algorithm 4 (lineₖᵢ) |
| 9: | else |
| 10: | (Z, δ, N_{branch}) ← Case4(node k, N_{branch}) |
| 11: | N_{branch} = N_{branch} + 1 |
| 12: | Return: Zₖᵢ, δₖᵢ, N_{branch} |

$Output \text{:} {Z}_{ij} = \frac{Z}{{N}_{branch}} {δ}_{ij} = δ$

With reference back to FIG. 1, an inverter 500 or another similar type of electronic device can be electrically interposed between the solar paneling 135 and the second residential load 134.

An inverter control signal u can be represented in the following general feedback control equation:

u=f(y−y^{ref},W)

where W denotes the network admittance, y−y^{ref} denotes a feedback signal and control signal u is a function of W and y−y^{ref}. Thus, it is apparent that inverter control is at least partially based on an assumption that network admittance W is known. However, as alluded to above, in many distribution grids that have a limited number of GMDs, there could be a correspondingly limited amount of information about network admittance W. Hence, in practice, the performance of inverters and their controllers is questionable, because their design is based on unrealistic guesses of the network admittance W. This is also one of the reasons why inverter controllers often require fine tuning at commissioning and installation even when they have passed manufacturing tests.

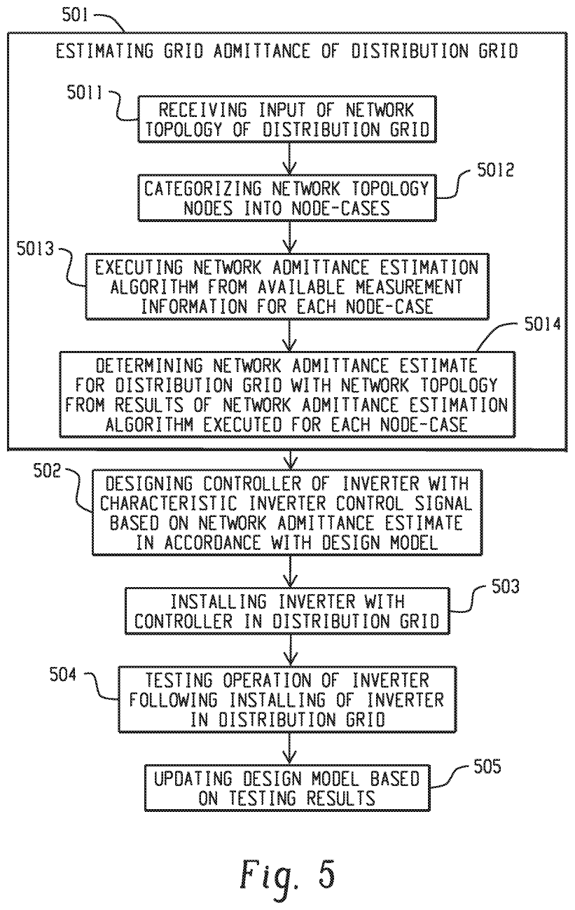

With reference to FIG. 5, improved inverter control can be achieved, however, by making use of the processes described herein to obtain accurate information about network admittance W of a distribution grid. That is, as shown in FIG. 5, a method of non-iteratively designing control architecture of an inverter for installation and use in a distribution grid is provided. The distribution grid includes a relatively low voltage tree structure and is electrically coupled to a transmission network comprising a relatively high voltage mesh network. The method includes estimating a grid admittance of the distribution grid (501), designing the inverter with a characteristic inverter control signal based on the network admittance estimate in accordance with a design model (502) and installing the inverter in the distribution grid (503). The estimating of the grid admittance of operation 501 includes one of a hybridized data-physics approach and an optimization-based approach and includes receiving an input of a network topology of a distribution grid (5011), categorizing the network topology into node-cases (5012) in a bottom-up direction, executing a network admittance estimation algorithm from available measurement information for each node-case (5013) and determining a network admittance estimate for the distribution grid with the network topology from results of the network admittance estimation algorithm executed for each node-case (5014). In accordance with embodiments, the method can further include testing an operation of the inverter following the installing of the inverter in the distribution grid (504) and updating the design model based on results of the testing (505).

The available measurement information is derived from devices, such as grid measurement devices (GMDs), distributed throughout the distribution grid and the node-cases include a case in which devices are present at parent and child nodes of a line of the distribution grid, a case in which a device is only present at a parent node of a line of the distribution grid, a case in which a device is only present at a child node of a line of the distribution grid and a case in which no device is present at parent or child nodes of a line of the distribution grid.

As another example of an implementation of the grid admittance estimation algorithms disclosed herein, industrial energy management systems can be operated based on grid admittance estimates. Here, state estimation tasks estimate system internal states based on measurement data Y assuming a network admittance matrix W is known and fixed. Without loss of generality, the relation can be written as:

Y=h(X,W)+e

where the right-hand side terms are unknown, X is an internal state and e denotes the error caused by network admittance matrix W (an accurate W will lead to a small e.) Thus, as a result of unknown admittance matrix W, existing state estimation tools are most likely not suitable for distribution networks due the prerequisite condition (accurate W) not being met. The algorithms described herein, however, provides distribution network admittance matrix W that, when combined with existing state estimation methods, will improve state estimation performance for distribution systems.

In addition, although large amounts of installed sensors would improve monitoring of a system, in practice, it is impossible to have expensive sensors installed everywhere. Hence, when designing a distribution grid with limited sensors and resources, it is important to determine how many sensors can be installed and where those sensors are really needed. The algorithms described herein provide instruction on these important questions.

For the installation of sensors, one should first prioritize all the power lines in terms of how critical each line is. Then starting from the most critical power line to the least critical power line, one should follow the procedure described as follows. Starting from the most critical line, which requires close monitoring, it is recommended to install sensors in the form of case 1 with two sensors installed on both nodes of a line. Notably, it is not required to install all sensors on the same line. If the line of interest shares its nodes with other lines (denoted by Q), as shown in Case 1, it is acceptable to install one of the sensors on a different line (the most critical line in Q) but at the shared node. It is recommended to have at most one sensor installed on each line when the number of sensors is limited, as this will increase the number of measured lines. If only one sensor is available, it is recommended to install sensor in the form of case 2. The same method is followed through all the power lines until all the sensors are allocated. For the non-critical power lines, they will be in the form of case 3 or case 4.

The operations described above may be carried out or performed in any suitable order as desired in various example embodiments of the invention. Additionally, in certain example embodiments, at least a portion of the operations may be carried out in parallel. Furthermore, in certain example embodiments, less, more, or different operations than those depicted.

Although specific embodiments of the invention have been described, one of ordinary skill in the art will recognize that numerous other modifications and alternative embodiments are within the scope of the invention. For example, any of the functionality and/or processing capabilities described with respect to a particular system, system component, device, or device component may be performed by any other system, device, or component. Further, while various illustrative implementations and architectures have been described in accordance with embodiments of the invention, one of ordinary skill in the art will appreciate that numerous other modifications to the illustrative implementations and architectures described herein are also within the scope of this invention. In addition, it should be appreciated that any operation, element, component, data, or the like described herein as being based on another operation, element, component, data, or the like may be additionally based on one or more other operations, elements, components, data, or the like. Accordingly, the phrase “based on,” or variants thereof, should be interpreted as “based at least in part on.”

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments of the invention described. Many modifications and variations will be apparent to those of ordinary skill in the art without departing from the scope and spirit of the described embodiments of the invention. The terminology used herein was chosen to best explain the principles of the embodiments of the invention, the practical application or technical improvement over technologies found in the marketplace, or to enable others of ordinary skill in the art to understand the embodiments of the invention described herein.

What is claimed is:

1. A method of estimating grid admittance, comprising:
receiving an input of a network topology of a distribution grid;
categorizing nodes of the network topology of the distribution grid into node-cases;
for each node-case, executing a network admittance estimation algorithm from available measurement information; and
determining a network admittance estimate for the distribution grid with the network topology from results of the network admittance estimation algorithm executed for each node-case.

2. The method according to claim 1, wherein the distribution grid comprises a relatively low voltage tree structure and is electrically coupled to a transmission network comprising a relatively high voltage mesh network.

3. The method according to claim 1, wherein the categorizing is executed in a bottom-up direction.

4. The method according to claim 1, wherein the available measurement information is derived from devices distributed throughout the distribution grid.

5. The method according to claim 4, wherein the node-cases comprise:
a case in which devices are present at parent and child nodes of a line of the distribution grid;
a case in which a device is only present at a parent node of a line of the distribution grid;
a case in which a device is only present at a child node of a line of the distribution grid; and
a case in which no device is present at parent or child nodes of a line of the distribution grid.

6. The method according to claim 1, wherein the network admittance estimation algorithm comprises one of a hybridized data-physics approach and an optimization-based approach.

7. A computer-implemented method of estimating grid admittance, comprising:
receiving an input of a network topology of a distribution grid;
categorizing nodes of the network topology of the distribution grid into node-cases;
for each node-case, executing a network admittance estimation algorithm from available measurement information; and
determining a network admittance estimate for the distribution grid with the network topology from results of the network admittance estimation algorithm executed for each node-case.

8. The computer-implemented method according to claim 7, wherein the distribution grid comprises a relatively low voltage tree structure and is electrically coupled to a transmission network comprising a relatively high voltage mesh network.

9. The computer-implemented method according to claim 7, wherein the categorizing is executed in a bottom-up direction.

10. The computer-implemented method according to claim 7, wherein the available measurement information is derived from devices distributed throughout the distribution grid.

11. The computer-implemented method according to claim 10, wherein the node-cases comprise:
a case in which devices are present at parent and child nodes of a line of the distribution grid;
a case in which a device is only present at a parent node of a line of the distribution grid;
a case in which a device is only present at a child node of a line of the distribution grid; and
a case in which no device is present at parent or child nodes of a line of the distribution grid.

12. The method according to claim 7, wherein the network admittance estimation algorithm comprises one of a hybridized data-physics approach and an optimization-based approach.

13. A non-iterative method of designing a controller of an inverter for installation in a distribution grid, the method comprising:
estimating a grid admittance of the distribution grid by receiving an input of a network topology of a distribution grid, categorizing nodes of the network topology of the distribution grid into node-cases, executing a network admittance estimation algorithm from available measurement information for each node-case and determining a network admittance estimate for the distribution grid with the network topology from results of the network admittance estimation algorithm executed for each node-case; and
designing the controller of the inverter with a characteristic inverter control signal based on the network admittance estimate in accordance with a design model.

14. The method according to claim 13, further comprising installing the inverter with the controller in the distribution grid.

15. The method according to claim 13, wherein the distribution grid comprises a relatively low voltage tree structure and is electrically coupled to a transmission network comprising a relatively high voltage mesh network.

16. The method according to claim 13, wherein the categorizing is executed in a bottom-up direction.

17. The method according to claim 13, wherein the available measurement information is derived from devices distributed throughout the distribution grid.

18. The method according to claim 17, wherein the node-cases comprise:
a case in which devices are present at parent and child nodes of a line of the distribution grid;
a case in which a device is only present at a parent node of a line of the distribution grid;
a case in which a device is only present at a child node of a line of the distribution grid; and
a case in which no device is present at parent or child nodes of a line of the distribution grid.

19. The method according to claim 13, wherein the network admittance estimation algorithm comprises one of a hybridized data-physics approach and an optimization-based approach.

20. The method according to claim 13, further comprising:
testing an operation of the inverter following the installing of the inverter in the distribution grid; and
updating the design model based on results of the testing.
